(19) United States
(12) Patent Application Publication
(10) Pub. No.: US 2024/0321364 A1
(43) Pub. Date: Sep. 26, 2024

(54) OPERATION METHOD OF MEMORY DEVICE, MEMORY DEVICE, MEMORY SYSTEM, AND ELECTRONIC APPARATUS

(71) Applicant: YANGTZE MEMORY TECHNOLOGIES CO., LTD., Wuhan (CN)

(72) Inventors: Kaiwei Li, Wuhan (CN); Jianquan Jia, Wuhan (CN); Junbao Wang, Wuhan (CN); An Zhang, Wuhan (CN); Yali Song, Wuhan (CN)

(21) Appl. No.: 18/223,435

(22) Filed: Jul. 18, 2023

(30) Foreign Application Priority Data
Mar. 22, 2023 (CN) 202310289275.0

(51) Int. Cl. G11C 16/34; G11C 16/04; G11C 16/10

(52) U.S. Cl. CPC G11C 16/3427; G11C 16/0483; G11C 16/10

(57) ABSTRACT

Implementations of the present disclosure disclose a memory operation method, a memory device, a memory system and an electronic apparatus. The memory device includes a memory stack structure, a select stack structure on the memory stack structure, a memory string including a first sub-string penetrating through the select stack structure, and a second sub-string penetrating through the memory stack structure, and including a first dummy memory cell adjacent to a plug, and a plurality of memory cells, a peripheral circuit connected with the memory string and configured to program the first dummy memory cell, and apply a first bias voltage to a first dummy word line coupled to the first dummy memory cell in a pre-charge stage of a program operation of one of the plurality of memory cells close to the plug.

### CROSS-REFERENCE TO RELATED APPLICATIONS

This application claims the benefit of priority to China Patent Application No. 202310289275.0, filed on Mar. 22, 2023, the content of which is incorporated herein by reference in its entirety.

### TECHNICAL FIELD

Implementations of the present disclosure relate to memory technology field,

particularly to an operation method of memory device, a memory device, a memory system and an electronic apparatus.

### BACKGROUND

With the continuous development of 3D NAND flash memory device, to increase storage capacity and storage density, the number of layers in the Z direction of a memory device has been increased constantly. The arrangement of channel structure in X-Y plane is optimized. For example, the channel structure is divided into a plurality of rows in a memory block by a staggered arrangement, and top select gate (TSG) cuts are located between channel structure rows to split a channel structure row in the memory block into several parts, thereby facilitating controlling operations on the split memory block such as programming and erasing. With the increasing number of memory cell layers, the structure in

Z direction becomes longer and longer. Upon implementation, a plurality of connected stacks may be used in the Z direction. In this case, while programming, a large amount of charges will accumulate at the connection between stacks, hence increasing programming interference.

### SUMMARY

Implementations of the present disclosure provide a memory operation method, a memory device, a memory system and an electronic apparatus that can improve the programming interference problem caused by electron accumulation at connections between stacks.

In a first aspect, an implementation of the present disclosure provides an operation method of a memory device, wherein the memory comprises a memory stack structure, a select stack structure and a plurality of memory strings, wherein the select stack structure is over the memory stack structure; each memory string comprises a first sub-string and a second sub-string connected by a plug; the first sub-string penetrates through the select stack structure; the second sub-string penetrates through the memory stack structure; and the second sub-string comprises a first dummy memory cell adjacent to the plug and a plurality of memory cells.

The operation method includes programming the first dummy memory cell; and/or applying a first bias voltage to a first dummy word line coupled to the first dummy memory cell in a pre-charge stage of a program operation of a memory cell close to the plug in a memory string, the first bias voltage being a negative voltage.

In some implementations, if only the first dummy memory cell is programmed, the operation method further includes: applying a second bias voltage to the first dummy word line, the second bias voltage being greater than the first bias voltage.

In some implementations, the first sub-string includes a top select gate, the operation method further includes: in the pre-charge stage, applying a first pass voltage to a top select line coupled to the top select gate.

In some implementations, the second sub-string comprises at least one second dummy memory cell and a second dummy word line coupled to the at least one second dummy memory cell respectively; and the operation method further comprises: applying a third bias voltage to the second dummy word line in the pre-charge stage, the third bias voltage being a negative voltage.

In some implementations, the first sub-string includes a top select gate, the operation method further includes: in the pre-charge stage, applying a first pass voltage to a top select line coupled to the top select gate.

In some implementations, the memory string is coupled to the bit line via the top select gate, and the operation method further includes applying a first pre-charge voltage to the bit line in the pre-charge stage, the first pre-charge voltage being greater than 0.

In some implementations, the second sub-string further includes a bottom select gate, the memory string is connected with the source line via the bottom select gate, and the operation method further includes: in the pre-charge stage, applying a second pass voltage to a bottom select line coupled to the bottom select gate; and applying a second pre-charge voltage to the source line; wherein the second pre-charge voltage is greater than 0.

In some implementations, the second sub-string further includes at least one third dummy memory cell between the plurality of memory cells and the bottom select gate, and the operation method further includes: applying a third pass voltage to the at least one third dummy memory cell in the pre-charge stage.

In some implementations, the operation method further includes in the pre-charge stage, applying a fourth bias voltage to a word line coupled to the plurality of memory cells.

In some implementations, the operation method further includes in a programming stage of the program operation on the memory cell, applying a fourth pass voltage to a word line coupled to unselected memory cells in the memory string and the first dummy word line, and applying a program voltage to a word line coupled to the memory cell.

In a second aspect, an implementation of the present disclosure provides a memory device including: a memory stack structure; a select stack structure; a plurality of memory strings, wherein the select stack structure is over the memory stack structure; each memory string comprises a first sub-string and a second sub-string connected by a plug; the first sub-string penetrates through the select stack structure; the second sub-string penetrates through the memory stack structure; and the second sub-string comprises a first dummy memory cell adjacent to the plug and a plurality of memory cells; a peripheral circuit connected with the plurality of memory strings and configured to program the first dummy memory cell; and/or apply a first bias voltage to a first dummy word line coupled to the first dummy memory cell in the pre-charge stage of the program operation of the memory cell close to the plug in a memory string, the first bias voltage being a negative voltage.

In some implementations, the peripheral circuit is further configured to: if only the first dummy memory cell is to be programmed, apply a second bias voltage to the first dummy word line in the pre-charge stage, the second bias voltage being greater than the first bias voltage.

In some implementations, the first sub-string includes a top select gate, the peripheral circuit is further configured to: in the pre-charge stage, apply a first pass voltage to the top select line coupled to the top select gate.

In some implementations, the second sub-string comprises at least one second dummy memory cell and a second dummy word line coupled to the at least one second dummy memory cell respectively; and the peripheral circuit is further configured to: apply a third bias voltage to the second dummy word line in the pre-charge stage, the third bias voltage being a negative voltage.

In some implementations, the first sub-string includes a top select gate, the peripheral circuit is further configured to: in the pre-charge stage, apply a first pass voltage to the top select line coupled to the top select gate.

In some implementations, the memory string is coupled to the bit line via the top select gate, the peripheral circuit is further configured to: apply a first pre-charge voltage to the bit line in the pre-charge stage, the first pre-charge voltage being greater than 0.

In some implementations, the second sub-string further includes a bottom select gate, the memory string is connected with the source line via the bottom select gate, and the peripheral circuit is further configured to: in the pre-charge stage, apply a second pass voltage to a bottom select line coupled to the bottom select gate; and apply a second pre-charge voltage to the source line; wherein the second pre-charge voltage is greater than 0.

In some implementations, the second sub-string further includes at least one third dummy memory cell between the plurality of memory cells and the bottom select gate, and the peripheral circuit is further configured to: apply a third pass voltage to the at least one third dummy memory cell in the pre-charge stage.

In some implementations, the peripheral circuit is further configured to: in the pre-charge stage, apply a fourth bias voltage to the word line coupled to the plurality of memory cells; in a programming stage of the program operation on the memory cell, apply a fourth pass voltage to a word line coupled to unselected memory cells in the memory string and the first dummy word line and apply a program voltage to a word line coupled to the memory cell.

In some implementations, the memory device further includes: a plurality of memory channel structures penetrating through the memory stack structure each corresponding to one second sub-string; top select gate cut structures and a plurality of select channel structures penetrating through the select stack structure, each select channel structure corresponding to one first sub-string; wherein the plurality of select channel structures and the plurality of memory channel structures are connected respectively; the plurality of select channel structures are arranged in rows along the extending direction of the top select gate cut structure; and the top select gate cut structures extend between adjacent rows of the select channel structures.

In some implementations, there are multiple rows of select channel structures between adjacent top select gate cut structures.

In some implementations, the select channel structure includes a dielectric core and a conductive layer and an insulating layer surrounding the dielectric core successively, wherein the conductive layer contacts the memory channel structure.

In a third aspect, an implementation of the present disclosure provides a memory system including: one or more memory devices; and a memory controller coupled to the memory devices and configured to control the memory devices.

In some implementations, the memory system is included in a solid-state disk SSD or a memory card.

In the fourth aspect, an implementation of the present disclosure provides an electronic apparatus including: the above-described memory system; and a host coupled to the memory system and configured to control the memory system.

Implementations of the present disclosure provide a memory operation method, a memory device, a memory system and an electronic apparatus, wherein the memory device includes: a memory stack structure, a select stack structure and a plurality of memory strings, wherein the select stack structure is over the memory stack structure; each memory string includes a first sub-string and a second sub-string connected by a plug; the first sub-string penetrates through the select stack structure; the second sub-string penetrates through the memory stack structure; and the second sub-string includes a first dummy memory cell adjacent to the plug and a plurality of memory cells; and the operation method includes: programming the first dummy memory cell; and/or applying a first bias voltage to a first dummy word line coupled to the first dummy memory cell in the pre-charge stage of the program operation of the memory cell close to the plug in a memory string, the first bias voltage being a negative voltage. With the operation method provided in implementations of the present disclosure, the threshold voltage of the first dummy memory cell is increased by programming the first dummy memory cell adjacent to the plug; or a negative bias voltage is applied to the first dummy word line coupled to the first dummy memory cell in the pre-charge stage of the program operation to effectively reduce electrons accumulated at the plug, thereby improving programming interference of memory cells close to the plug.

### BRIEF DESCRIPTION OF DRAWINGS

In the figures drawn not necessarily to scale, same reference numerals may describe similar parts in different views. Same numerals with different character suffixes may represent different instances of similar parts. The accompanying drawings illustrate various implementations discussed in the present document in general by example rather than limitation.

FIG. 1 illustrates a block diagram of an example electronic apparatus with a memory system;

FIG. 2 illustrates a schematic diagram of an example memory card with a memory device provided in an implementation of the present disclosure;

FIG. 3 illustrates a schematic diagram of an example solid state disk (SSD) with a memory provided in an implementation of the present disclosure;

FIG. 4 illustrates a schematic diagram of an example memory device containing a peripheral circuit provided in an implementation of the present disclosure;

FIG. 5 illustrates a schematic diagram of an example memory device containing a memory array and a peripheral circuit provided in an implementation of the present disclosure;

FIG. 6 illustrates a structure diagram of a memory array provided in an implementation of the present disclosure in X-Y-Z directions;

FIG. 7 illustrates a structure diagram of a memory array provided in an implementation of the present disclosure in X-Y direction;

FIG. 8 illustrates a structural diagram I of a memory string provided in an implementation of the present disclosure;

FIG. 9 illustrates a structural diagram II of a memory string provided in an implementation of the present disclosure;

FIG. 10 illustrates a flow chart of a memory operation method provided in an implementation of the present disclosure;

FIG. 11 illustrates a physical structure diagram of a memory string provided in an implementation of the present disclosure;

FIG. 12 illustrates a flow chart of another memory operation method provided in an implementation of the present disclosure;

FIG. 13 illustrates a flow chart of yet another memory operation method provided in an implementation of the present disclosure;

FIG. 14 illustrates a flow chart of another memory operation method provided in an implementation of the present disclosure;

FIG. 15 illustrates a timing diagram of applying voltages in memory strings in a program operation for a memory device;

FIG. 16 illustrates a timing diagram I of applying voltages in memory strings in a program operation for a memory device provided in an implementation of the present disclosure;

FIG. 17 illustrates an effect diagram of adopting the program operation shown in FIG. 16 as provided in an implementation of the present disclosure;

FIG. 18 illustrates a timing diagram II of applying voltages in memory strings in a program operation for a memory provided in an implementation of the present disclosure;

FIG. 19 illustrates an effect diagram of adopting the program operation shown in FIG. 18 as provided in an implementation of the present disclosure; and

FIG. 20 illustrates a physical structure diagram of a memory array provided in an implementation of the present disclosure.

### DETAILED DESCRIPTION

Example implementations disclosed by the present disclosure will be described in greater detail below with reference to the accompanying drawings. Although example implementations of the present disclosure are shown in drawings, it is to be appreciated that the present disclosure may be implemented in various forms rather than being limited to the specific implementations as set forth herein. In contrast, these implementations are provided to understand the present disclosure more thoroughly and convey the scope of the present disclosure completely to those skilled in the art.

In the following description, a large number of specific details are presented to provide thorough understanding of the present disclosure. However, it is obvious to one skilled in the art that the present disclosure may be implemented without one or more of these details. In other examples, in order to avoid confusion with the present disclosure, some technical features well known in the art are not described. That is, not all features of the practical implementations are described herein, and well-known functions and structures are not described.

In the accompanying drawings, sizes and relative sizes of layers, regions and elements may be exaggerated for the purpose of clarity. The same reference numerals refer to the same elements throughout the specification.

It should be understood that while an element or a layer is the to be “on”, “adjacent to”, “connected to” or “coupled to” other elements or layers, it may be directly on, adjacent to, connected to or coupled to other elements or layers, or there may be intervening elements or layers. To the contrary, while an element is the to be “directly on”, “directly adjacent to”, “directly connected to” or “directly coupled to” other elements or layers, there is no intervening elements or layers. It is to be appreciated that although terms such as first, second, third etc. may be used to describe elements, components, regions, layers and/or parts, these elements, components, regions, layers and/or parts should not be limited by these terms. These terms are only used to differentiate one element, component, region, layer or part from another element, component, region, layer or part. Therefore, without departing from the teaching of the present disclosure, the first element, component, region or part discussed below may represent the second element, component, region, layer or part. While discussing the second element, component, region, layer or part, it does not necessarily indicate there is the first element, component, region, layer or part in the present disclosure.

Spatial relationship terms such as “under”, “below”, “lower”, “beneath”, “over”, “on” etc. may be used herein for convenient description to describe the relationship of one element or feature shown in the drawings relative to other elements or features. It is to be appreciated that spatial relationship terms are further intended to include different orientations of devices in use and operation in addition to orientations shown in the figures. For example, if the device in a figure is inverted, then an element or feature described as “under” or “below” or “beneath” another element or feature will be oriented as being “on” the other element or feature. Accordingly, example terms “under” and “below” may include two orientations “on” and “under”. A device may be otherwise oriented (rotated by 90 degrees or other orientations) and spatial description terms used herein should be interpreted accordingly.

Terms are used herein only for describing specific implementations rather than limiting the present disclosure. As used herein, the singular form “a”, “an” and “the” are also intended to include the plural form unless otherwise stated in the context. It is also understood that while used in the description, terms “comprise” and/or “include” confirm the presence of the features, integers, steps, operations, elements and/or components, but do not exclude the presence or addition of one or more other features, integers, steps, operations, elements, components and/or groups. As used herein, the term “and/or” includes any and all combinations of relevant listed items.

In order to understand characteristics and technology contents of implementations of the present disclosure in more detail, implementations of implementations of the present disclosure will be described with reference to the accompanying drawings that are only for the purpose of reference rather than limiting implementations of the present disclosure.

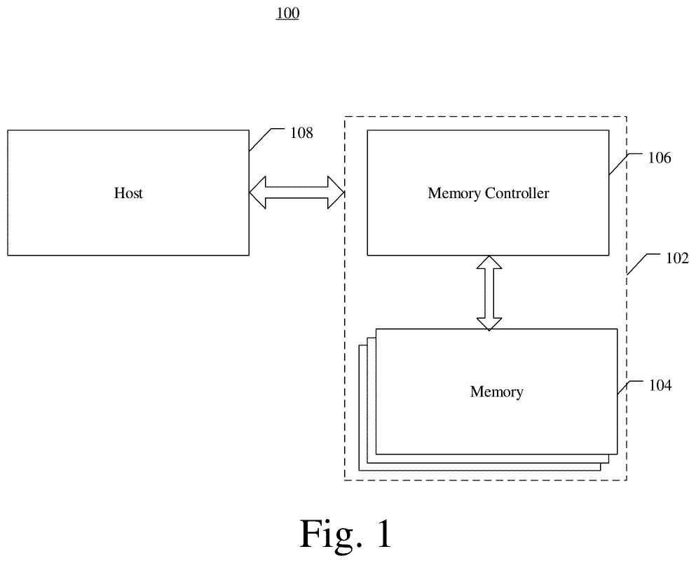

FIG. 1 illustrates a block diagram of an example electronic apparatus with a memory system. In FIG. 1, the electronic apparatus 100 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic apparatus having memory devices therein. As shown in FIG. 1, the electronic apparatus 100 may include a host 108 and a memory system 102, wherein the memory system 102 has one or more memory devices 104 and a memory controller 106, the host 108 may be a processor of the electronic apparatus such as a central processing unit (CPU) or a system-on-chip (SoC), in which the SoC may be for example an application processor (AP). The host 108 may be configured to send data to the memory device 104 via the memory controller 106 or receive data from the memory device 104 via the memory controller 106. Specifically, the memory device 104 may be any of the memory devices disclosed in the present disclosure. For example, phase change random access memory devices (PCRAM) and three-dimensional NAND flashes etc. It is noted that, in the following descriptions, the term “memory device” may also be referred to “memory” for short.

According to some implementations, the memory controller 106 is coupled to the memory device 104 and the host 108, and is configured to control the memory device 104. The memory controller 106 can manage the data stored in the memory device 104 and communicate with the host 108. In some implementations, the memory controller 106 is designed for operating in a low duty-cycle environment such as secure digital (SD) cards, compact Flash (CF) cards, universal serial bus (USB) Flash drives, or other media for use in electronic apparatuses of low duty-cycle environments such as personal computers, digital cameras, mobile phones, etc. In some implementations, the memory controller 106 is designed to operate in high duty cycle environments such as solid-state drives (SSDs) or embedded multimedia cards (eMMCs), wherein SSDs or eMMCs are used as e.g., data storages and enterprise memory arrays of the mobile devices of high duty cycle environments such as smart phones, tablet computers and laptop computers. The memory controller 106 can be configured to control operations of the memory device 104, such as read, erase, and program operations.

In some implementations, the memory controller 106 can also be configured to manage various functions with respect to the data stored or to be stored in the memory device 104 including, but not limited to bad-block management, garbage collection, logical-to-physical address conversion, wear leveling, etc. In some implementations, the memory controller 106 is further configured to process error correction codes (ECCs) with respect to the data read from or written to the memory device 104. In some implementations, any other suitable functions may be performed by the memory controller 106 as well, for example, formatting the memory device 104. The memory controller 106 can communicate with an external device (e.g., the host 108) according to a particular communication protocol. For example, the memory controller 106 may communicate with the external device through at least one of various interface protocol, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc. These interfaces may also be referred to as front-end interfaces. In some implementations, the memory controller 106 implements command/data interactions with the memory device 104 via a plurality of configured channels. These channels are also referred to as back-end interfaces.

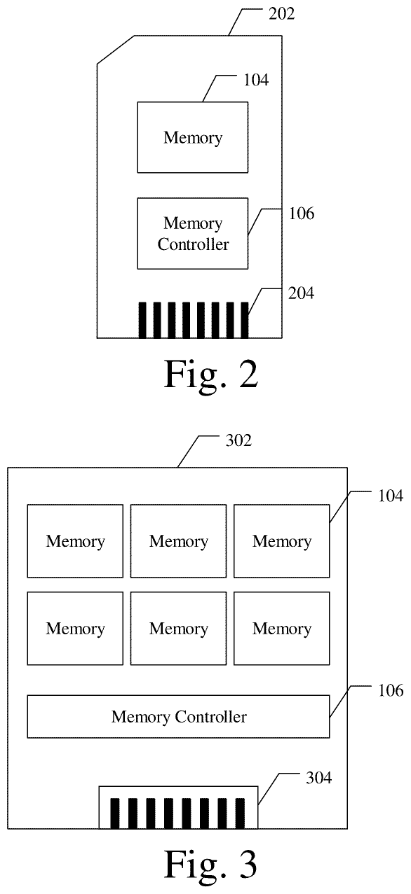

In some implementations, the memory controller 106 and one or more memory devices 104 can be integrated into various types of storage apparatuses, for example, be included in the same package, such as a universal Flash storage (UFS) package or an eMMC package. That is, the memory system 102 can be implemented and packaged into different types of end electronic products. In one example as shown in FIG. 2, the memory controller 106 and a single memory device 104 can be integrated into a memory card 202. The memory card may include a PC card (PCMCIA, Personal Computer Memory Card International Association), a CF card, a smart media (SM) card, a memory stick, a multimedia card (MMC, RS-MMC, MMCmicro), a SD card (SD, miniSD, microSD, SDHC), a UFS etc. The memory card may also include a memory card connector 204 coupling the memory card and the host (e.g., the host 108 in FIG. 1).

In another example as shown in FIG. 3, the memory controller 106 and multiple memory devices 104 can be integrated into an SSD 302. The SSD may also include an SSD connector 304 coupling the SSD and the host (e.g., the host 108 in FIG. 1). In some implementations, the memory capacity and/or operating speed of SSD are greater than the memory capacity and/or operating speed of the memory card.

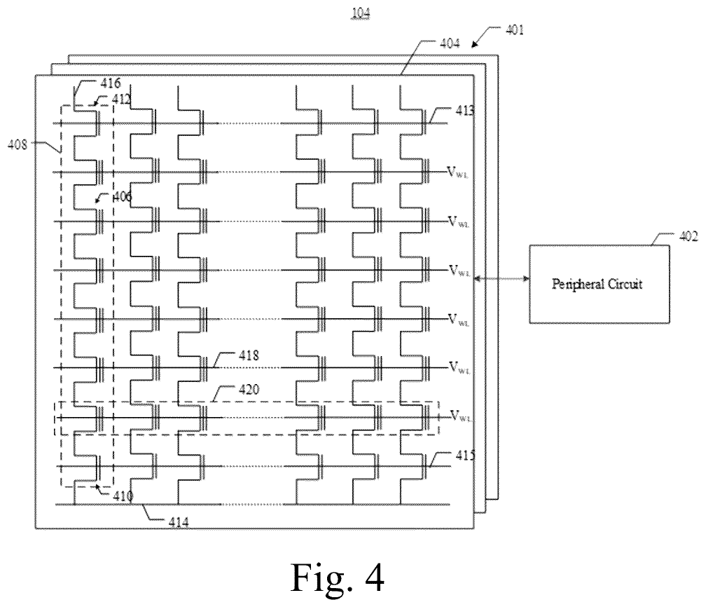

In some implementations, the structure of the memory device 104 may be an example memory containing a peripheral circuit as shown in FIG. 4. As shown in FIG. 4, the memory device 104 may include a memory array 401 and a peripheral circuit 402 coupled to the memory array 401, wherein the memory array 401 may be a NAND flash memory array, wherein the memory cells 406 are provided in form of an array of NAND memory strings 408 and each NAND memory string 408 extends vertically over the substrate (not shown). In some implementations, each NAND memory string 408 includes a plurality of memory cells 406 coupled in series and stacked vertically. Each memory cell 406 can retain continuous analog values, for example, voltages or charges, depending on the number of electrons trapped in the storage region of the memory cell 406. Each memory cell 406 may be a memory cell of a floating-gate type that includes floating-gate transistors or a memory cell of a charge trapping type that includes charge trapping transistors.

In some implementations, each memory cell 406 is a single-level cell (SLC) that has two possible data states and can therefore store one bit of data. For example, the first data state “0” may correspond to the first voltage range, and the second data state “1” may correspond to the second voltage range. In some implementations, the first voltage range and the second voltage range may be referred to as the threshold voltage distribution of a memory cell. In some implementations, each memory cell 406 is a multi-level cell (MLC) that has more than four data states and store multiple bits of data (i.e., multi-value storage). For example, an MLC may store two bits per memory cell, three bits per memory cell (also known as TLC, Trinary-Level Cell) or four bits per memory cell (also known as QLC, Quadruple-Level Cell), etc. Among them, data states of whatever types of memory cells contain erasing state and programming state. In some implementations, while performing program operation on a memory cell, the memory cell in erasing state is programmed to a certain programming state. Generally, a voltage value in the voltage range corresponding to the programming state of a memory cell is greater than that in the voltage range corresponding to the erasing state.

As shown in FIG. 4, each NAND string 408 may include a source select gate (SSG) 410 at its source end and a drain select gate (DSG) 412 at its drain end, wherein in some implementations, the source select gate (SSG) 410 may also be referred to as the bottom select gate (BSG) and the drain select gate (DSG) 412 may also be referred to as the top selective gate (TSG). SSG 410 and DSG 412 may be configured to activate the selected NAND memory string 408 (a column of the array) during reading and programming (or writing) operations. In some implementations, sources of NAND memory strings 408 in the same block 404 are coupled through the same source line (SL) 414, such as the common SL. In other words, according to some implementations, all NAND memory strings 408 in the same block 404 have an array common source (ACS). According to some implementations, DSG 412 of each NAND memory string 408 is coupled to a corresponding bit line 416 and data may be read from and written into the bit line 416 via an output bus (not shown). In some implementations, each NAND memory string 408 is configured to be selected or deselected by applying a select voltage (for example higher than the threshold voltage of the transistor having DSG 412) or a deselect voltage (for example, 0 volt (V)) to the corresponding DSG 412 via one or more DSG lines 413 and/or applying a select voltage (for example higher than the threshold voltage of the transistor having SSG 410) or a deselect voltage (for example, 0V) to the corresponding SSG 410 via one or more SSG lines 415. In some implementations, the transistor corresponding to SSG 410 may be referred to as the lower selector, or the bottom select gate; and the transistor corresponding to DSG 412 may be referred to as the upper selector, or the top select gate.

As shown in FIG. 4, the NAND memory string 408 may be organized into a plurality of blocks 404 and each block 404 may have a common source line 414 (coupled to ground for example). In some implementations, each block 404 is the basic data unit having erase operation. That is, all memory cells 406 on the same block 404 are erased at the same time. In order to erase the memory cells 406 in a selected block 404, it is possible to bias the source line 414 coupled to the selected block 404 and the unselected blocks 404 in the same plane as the selected block 404 with an erase voltage (Vers) (for example, a high positive voltage of 20V or higher). It will be appreciated that in some examples, it is possible to execute erase operation on the semi-block level, the quarter-block level or a level of any suitable number of blocks or any suitable fraction of a block. Memory cells 406 in adjacent NAND memory strings 408 may be coupled via the word line 418 that chooses which row of the memory cells 406 is subject to the reading and program operations. In some implementations, memory cells 406 coupled to the same word line 418 are referred to as a page 420. Page 420 is the basic data unit for programming or reading operation. The size of a page 420 in bits may be relevant to the number of NAND memory strings 408 in a block 404 that are coupled to the word line 418. Each word line 418 may include a plurality of control gates (gate electrodes) at each memory cell 406 in the respective page 420 and gate lines for coupling control gates.

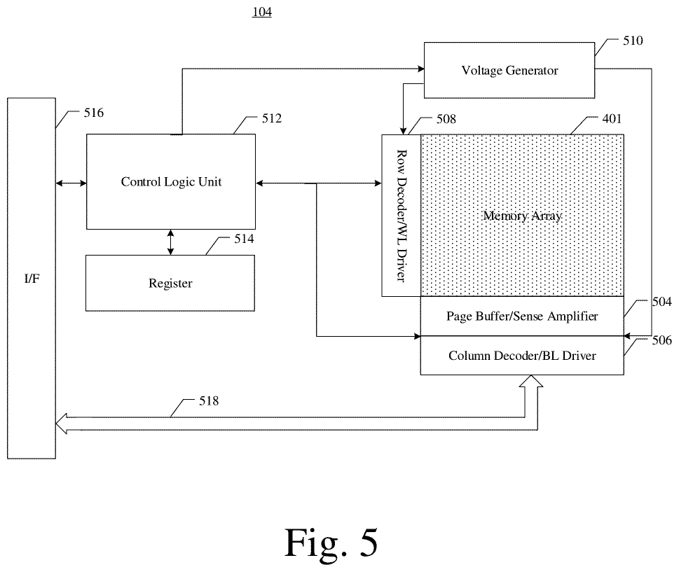

Referring back to FIG. 4, the peripheral circuit 402 may be coupled to the memory array 401 through the bit line 416, the word line 418, the source line 414, the SSG line 415 and the DSG line 413. The peripheral circuit 402 may include any suitable analog, digital and hybrid signal circuits for facilitating operation of the memory array 401 by applying voltage signals and/or current signals to each target memory cell 406 via bit lines 416, word lines 418, source lines 414, SSG lines 415 and DSG lines 413 and sensing voltage signals and/or current signals from each target memory cell 406. The peripheral circuit 402 may include various types of peripheral circuits formed by metal-oxide-semiconductor (MOS) technology. As an example, FIG. 5 shows some example peripheral circuits. The peripheral circuit 402 includes a page buffer/sense amplifier 504, a column decoder/bit line driver 506, a row decoder/word line driver 508, a voltage generator 510, a control logic unit 512, a register 514, an interface 516 and a data bus 518. It should be understood that, in some examples, additional peripheral circuits not shown in FIG. 5 may be further included.

In some implementations, the page buffer/sense amplifier 504 may be configured to read data from the memory array 401 and program (write) data to the memory array 401 according to control signals from control logic unit 512. In one example, the page buffer/sense amplifier 504 may store a page of programming data (writing data) to be programed into a page 420 of the memory array 401. In another example, the page buffer/sense amplifier 504 may execute the programming verification operation to ensure that the data has been properly programed into the memory cells 406 coupled to the selected word line 418. In yet another example, the page buffer/sense amplifier 504 may also sense a low-power signal from a bit line 416 indicating the data bit stored in a memory cell 406 and amplify the small voltage swing to an identifiable logic level in the read operation. The column decoder/bit line driver 506 may be configured to be controlled by the control logic 512 and select one or more NAND memory strings 408 by applying a bit line voltage generated by the voltage generator 510.

The row decoder/word line driver 508 may be configured to be controlled by the control logic 512, and select/deselected blocks 404 of the memory array 401 and select/deselect word lines 418 of the block 404. The row decoder/word line driver 508 may be further configured to drive word lines 418 using word line voltages generated by the voltage generator 510. In some implementations, the row decoder/word line driver 508 may also select/deselect and drive SSG lines 415 and DSG lines 413. In some implementations, the row decoder/word line driver 508 is configured to execute erasing operation on the memory cells 406 coupled to the (one or more) selected word lines 418. The voltage generator 510 may be configured to be controlled by the control logic 512 and generate the word line voltage (for example, read voltage, program voltage, pass voltage, local voltage, verification voltage, etc.), the bit line voltage (the voltage provided to the bit line) and the source line voltage (the voltage provided to the source line) to be provided to the memory array 401.

The control logic unit 512 may be coupled to each peripheral circuit described above and configured to control operations of each of the peripheral circuits. The register 514 may be coupled to the control logic unit 512 and include a status register, a command register and an address register to store status information, command operation codes (OP codes) and command addresses for controlling operations of each of the peripheral circuits. The interface 516 may be coupled to the control logic 512, and serve as a control buffer to buffer control commands received from the host (not shown) and relay them to the control logic unit 512, and buffer status information received from the control logic unit 512 and relay them to the host. The interface 516 may be further coupled to the column decoder/bit line driver 506 via the data bus 518 and serve as a data I/O interface and a data buffer to buffer data and relay it to the memory array 401 or relay or buffer data from the memory array 401. That is, the interface 516 herein is the interface coupled to the back-end interface of the afore-mentioned memory controller. Namely the interface 516 may also be the interface for communication between the memory and the memory controller.

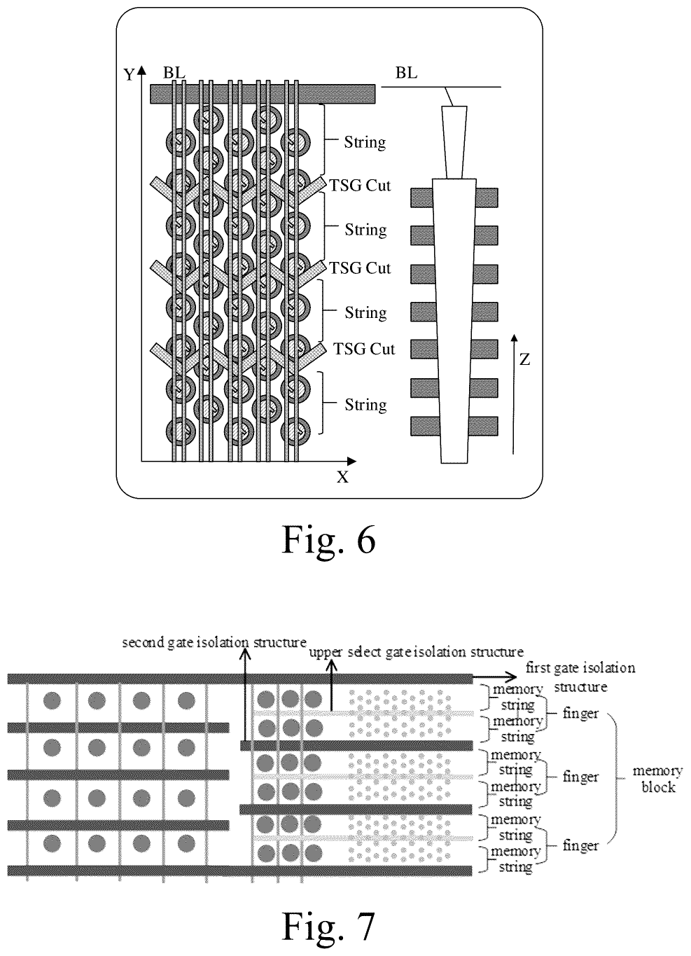

In the above, FIGS. 4 and 5 depict the structure of the memory array, the structure of the peripheral circuit and the connection between the memory array and the peripheral circuit from the perspective of circuit logic. In terms of physical structure, the integration density of a 3D NAND memory array may be increased by arranging memory cells in three dimensions on the substrate, as shown in FIGS. 6 to 7 for example. FIG. 6 illustrates a structure diagram of a memory array provided in an implementation of the present disclosure in X-Y-Z directions; and FIG. 7 illustrates a structure diagram of a memory array provided in an implementation of the present disclosure in X-Y direction. As can be seen from FIGS. 6 to 7, the storage density of a 3D NAND memory array may be improved by constantly increasing the number of layers in the Z direction. For example, there are a plurality layers of memory cells in the Z direction in FIG. 6, and in the X-Y direction, the channel structure in the memory block is divided into several parts by disposing top select gate cuts (TSG cuts) in the dummy channel (DMY channel hole) structure to facilitate controlling programming and erasing operations and the like on the divided memory block. For example, in the X-Y direction in FIG. 6, the memory block is divided into 4 strings by three TSG cuts. However, it should be known that FIG. 6 only illustrates the function of TSG cuts, and the size of the memory array is not limited to that shown in FIG. 6. In fact, the memory array extends in the X-Y direction. A more detailed description of the extension of the memory array in X-Y direction is as shown in FIG. 7.

In FIG. 7, the memory array of the 3D NAND memory devices consists of several rows of memory cells staggered and parallel to gate isolation structures in which every four rows of memory cells are separated by a gate isolation structure and an upper select gate isolation structure (i.e., TSG cut) and each row of memory cells includes a plurality of memory cells. The gate isolation structures may include first gate isolation structures and second gate isolation structures, wherein the first gate isolation structures divide the memory array into a plurality of memory blocks, a plurality of second gate isolation structures may divide a memory block into a plurality of fingers and an upper select gate isolation structure disposed in the middle of each finger may divide the finger into two parts, thereby dividing the finger into two memory strings. The one memory block shown in FIG. 7 contains 6 memory strings. In practical applications, the number of memory strings in a memory block is not limited thereto. The memory cells in one memory block coupled to a certain word line may be referred to as a memory page. It is to be noted that the number 5 of rows of memory cells between the gate isolation structures and the upper select gate isolation structures shown in FIG. 7 is only an illustrative example, and not used for limiting the number of rows of memory cells contained in one finger of the 3D NAND memory in the present disclosure. In practical application process, the number of rows of memory cells contained in a finger may be adjusted according to practical conditions, such as 2, 4, 8, 16 etc.

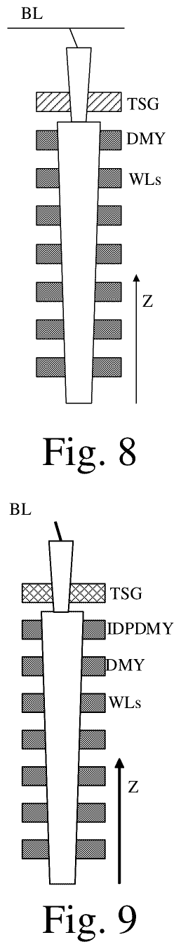

In practical application process, partial storage space has to be sacrificed due to the presence of TSG cuts. In order to address the above-described problem, as shown in FIGS. 8 and 9, a TSG deck scheme is adopted. That is, the critical dimension (CD, herein referring to the diameter of the channel structure of TSG) of TSG is reduced, thereby enlarging the space between TSGs for cutting. In terms of process, in order to connect the TSG deck with the deck on which the memory cells reside (which may be one deck and may include connected upper deck and down deck), a plug (such as a poly plug) would be added between the TSG deck and the deck on which the memory cells reside (e.g., upper deck) to communicate channels of the upper and down decks. However, research revealed that large number of charges might accumulate at the poly plug in the programming verification stage due to the special structure here, and the accumulated charges here would interfere with nearby word lines, increasing interference to their programming. It is to be noted that FIG. 8 is different from FIG. 9 only in that the deck on which memory cells reside contains a different number of dummy (DMY) memory cells, wherein FIG. 8 only contains one DMY, while FIG. 9 contains DMYs and IDPDMYs. That is, the deck on which memory cells reside has different structures in practical application processes depending on different demands. Its structure is not limited herein.

In order to address the programming interference problem as described above due to plugs, an implementation of the present disclosure provides an operating method of a memory to reduce charges accumulated at the poly plugs during programming verification stage to improve programming interference.

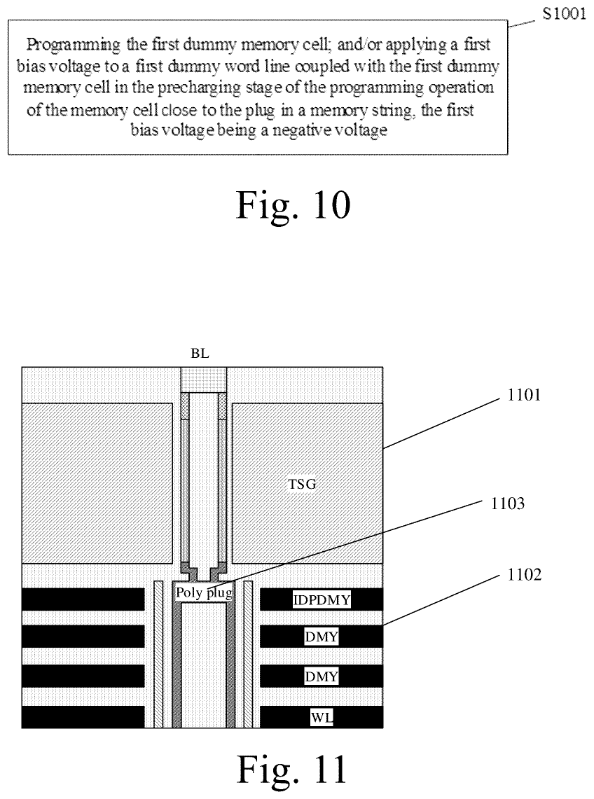

Specifically, as shown in FIG. 10, an implementation of the present disclosure provides a memory operation method. The memory may include: a memory stack structure, a select stack structure and a plurality of memory strings, wherein the select stack structure is over the memory stack structure: each memory string includes a first sub-string and a second sub-string connected by a plug: the first sub-string penetrates through the select stack structure: the second sub-string penetrates through the memory stack structure: and the second sub-string includes a first dummy memory cell adjacent to the plug and a plurality of memory cells. With this structure, the operation method may include: S1001: programming the first dummy memory cell; and/or applying a first bias voltage to a first dummy word line coupled to the first dummy memory cell in the pre-charge stage of the program operation of the memory cell close to the plug in a memory string, the first bias voltage being a negative voltage.

It is to be noted that the memory stack structure may be for example the afore-mentioned deck on which memory cells reside; the select stack structure may be for example the afore-mentioned TSG deck; and the plurality of memory strings may include for example the plurality of memory strings as shown in previously described FIG. 4 or 9, wherein each memory string includes a first sub-string and a second sub-string connected by a plug; the first sub-string penetrates through the select stack structure; the second sub-string penetrates through the memory stack structure; and the second sub-string includes a first dummy memory cell adjacent to the plug and a plurality of memory cells.

As to the structure of the memory device, an implementable form is shown in FIG. 11 which illustrates a structural diagram I of a memory string provided in an implementation of the present disclosure. In FIG. 11, 1101 denotes the first sub-string of the memory string, which is TSG; 1102 denotes the second sub-string of the memory string, which includes the first dummy cell IDPDMY, at least one second dummy cell DMY and a plurality of memory cells; and 1103 denotes the plug connecting the first sub-string and the second sub-string of the memory string (poly plug in FIG. 11, which also may be other type of available plug). With the memory string shown in FIG. 11, study revealed that while programming memory cells close to the plug, large number of charges would accumulate at the plug, which will interfere with the voltage variation on the word line coupled to the adjacent memory cells, thereby increasing programming interference of the memory cells.

The cause for accumulating large number of charges at the plug is as follows. Firstly, in order to connect the first sub-string and the second sub-string of the memory string, the width of the plug structure (e.g., hundreds of nanometers) is larger than that of the channel of the first dummy memory cell or memory cells contained in the second sub-string (e.g., only about a dozen nanometers), which cause a weak gate control over the plug by the control gate (e.g., the control gate of the IDPDMY shown in FIG. 11) nearby the plug. Secondly, due to the process, the control gate near the plug (e.g., the control gate of the IDPDMY shown in FIG. 11) is far from the plug, which causes a weaker gate control over the plug by the control gate nearby the plug. Thirdly, due to the process, the plug is damaged while forming the plug by etching, which causes the plug to have many defects and can capture many electrons. While programming the memory cells in the memory string, the channel of the memory string is turned on, a large amount of electrons are traveling in the channel. Based on the above two causes, electrons at the plug cannot move out. And based on the last cause, many electrons can be captured at the plug. Therefore, large number of electrons will accumulate at the plug during the programming of the memory string, thereby causing programming interference of memory cells close to the plug.

In view of the above-described technical problem, an implementation of the present disclosure provides the operation method as shown in FIG. 10 to improve programming interference.

The technical solution described above in S1001 may include three operation schemes. In the first scheme, the first dummy memory cell is programmed to increase the threshold voltage of the first dummy memory cell, thereby enhancing the gate control capability over the nearby plug by the control gate of the first dummy memory cell, reducing electrons staying at the plug during the program operation of the memory cells close to the plug. In the second scheme, in the pre-charge stage of the program operation of the memory cells close to the plug, a negative first bias voltage is applied to the first dummy word line of the first dummy memory cell. At this time, the negative potential is coupled to the channel corresponding to the first dummy memory cell. Since electrons carry negative charges, according to the fact that like charges repel each other, electrons at the plug will not move to channels at the memory cells. That is, migration of electrons at the plug to the word line of the memory cells is prevented, namely reducing interference on the word lines and improving programming interference. In the third scheme, the above-described two schemes are combined to both reduce electrons staying at the plug and prevent electrons at the plug from migrating to the word line of the memory cells, achieving a better effect.

In some implementations, if only the first dummy memory cell is programmed, the operation method further includes: applying a second bias voltage to the first dummy word line, the second bias voltage being greater than the first bias voltage.

It is to be noted that while adopting the above-described first scheme, it is possible to apply a second bias voltage to the first dummy word line in the pre-charge stage of the program operation of the memory cells close to the plug. The second bias voltage may be greater than the first bias voltage. That is, after having increased the threshold voltage of the first dummy memory cell, while programming the memory cells close to the plug, in the pre-charge stage, the bias voltage applied to the first dummy word line of the first dummy memory cell may be slightly greater than the first bias voltage, which can improve programming interference. For example, the first bias voltage may be −2 volts (V); and the second bias voltage may be 0V.

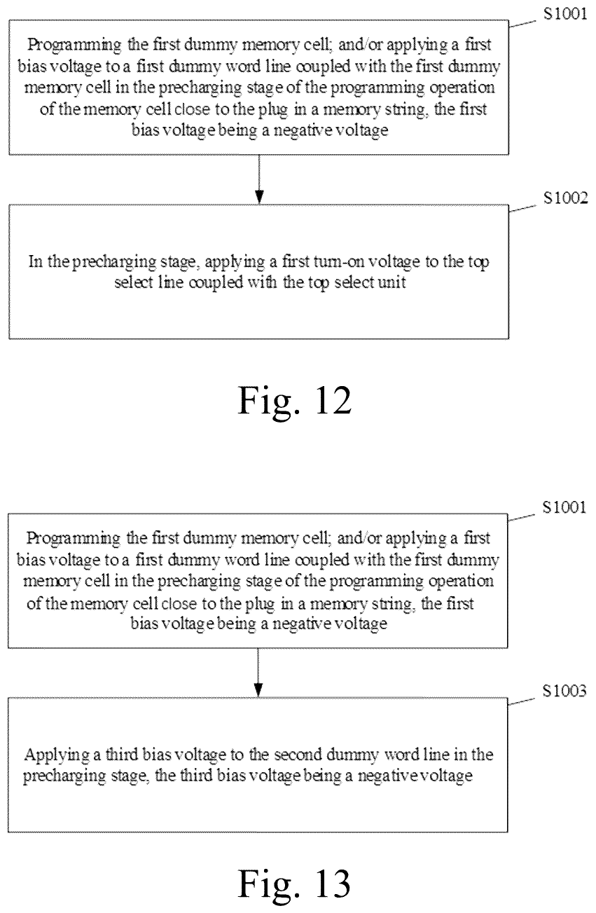

In some implementations, as shown in FIG. 12, if the first sub-string includes a top select gate, the operation method provided in the implementation of the present disclosure may further include: S1002: in the pre-charge stage, applying a first pass voltage to the top select line coupled to the top select gate.

It is to be noted that, based on the above technical solution as shown in FIG. 10, if the first sub-string includes a top select gate, then in the pre-charge stage, a first pass voltage is applied to the top select line coupled to the top select gate to turn on the top select gate. This operation enables electrons at the plug to move towards the bit line under the action of the positive bias voltage on the bit line, thereby drawing electrons out of the channel via the bit line and improving programming interference.

In some implementations, as shown in FIG. 13, the second sub-string includes at least one second dummy memory cell and a second dummy word line coupled to the at least one second dummy memory cell respectively and the operation method provided in the implementation of the present disclosure further includes: S1003: applying a third bias voltage to the second dummy word line in the pre-charge stage, the third bias voltage being a negative voltage.

It is to be noted that based on the above technical scheme as shown in FIG. 10, applying the third negative bias voltage to the second dummy word line couples a negative potential into the channel corresponding to the second dummy memory cell to prevent electrons at the plug from moving to the word line of memory cells. That is, the function of the third bias voltage is same as that of the first bias voltage. In practical implementation, the third bias voltage may be equal to or not equal to the first bias voltage.

Upon specific implementation, it is possible to apply the third bias voltage only to the second dummy word line of the second dummy memory cell adjacent to the first dummy memory cell; and it is also possible to apply the third bias voltage to some or all of the second dummy word line in at least one second dummy memory cell.

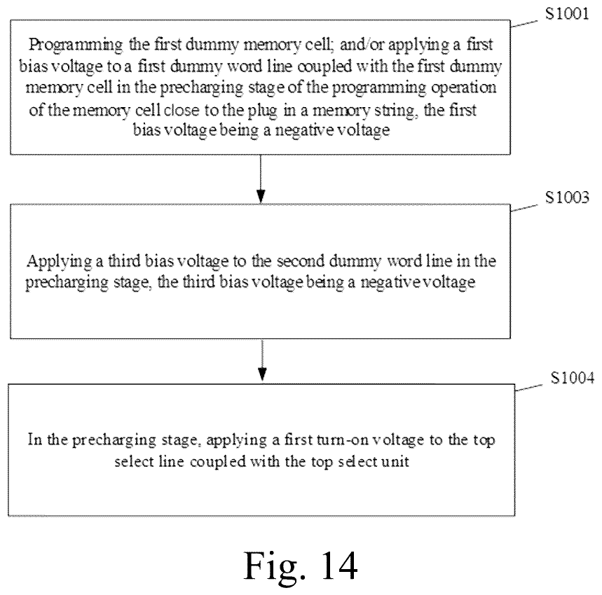

In some implementations, as shown in FIG. 14, if the first sub-string includes a top select gate, the operation method further includes: S1004: in the pre-charge stage, applying a first pass voltage to the top select line coupled to the top select gate.

It is to be noted that on the basis of the above technical solution as shown in FIG. 13, if the first sub-string includes a top select gate, then in the pre-charge stage, a first pass voltage is applied to the top select line coupled to the top select gate to turn on the top select gate. This operation enables electrons at the plug to move towards the bit line, thereby drawing electrons out of the channel via the bit line and improving programming interference.

In some implementations, the memory string is coupled to the bit line via the top select gate, and in the pre-charge stage of the program operation, the operation method may further include: applying a first pre-charge voltage to the bit line in the pre-charge stage, the first pre-charge voltage being greater than 0.

In some implementations, the second sub-string further includes a bottom select gate, the memory string is connected with the source line via the bottom select gate, and the operation method further includes: in the pre-charge stage, applying a second pass voltage to the bottom select line coupled to the bottom select gate; and applying a second pre-charge voltage to the source line; wherein the second pre-charge voltage is greater than 0.

In some implementations, the second sub-string further includes at least one third dummy memory cell between the plurality of memory cells and the bottom select gate, and the operation method further includes: applying a third pass voltage to the at least one third dummy memory cell in the pre-charge stage.

In some implementations, the operation method further includes: in the pre-charge stage, applying a fourth bias voltage to the word line coupled to the plurality of memory cells.

It is to be noted that the above-described operations are operations in the pre-charge stage of the program operation, wherein the first pre-charge voltage may be equal to or not equal to the second pre-charge voltage, which have the same function. The second pass voltage and the third pass voltage may be the same or different, wherein the second pass voltage and the third pass voltage are the same when the bottom select gate and the third dummy memory cells are the same in terms of type and threshold voltage; and the second pass voltage and the third pass voltage are different when the bottom select gate and the third dummy memory cells are different in terms of type and threshold voltage. Similarly, the relationship between the first pass voltage, the second pass voltage and the third pass voltage may also be understood with reference to the above description. In the practical application process, for convenient implementation, the first pass voltage, the second pass voltage and the third pass voltage may be set to be greater than the maximum of the threshold voltages of the above-described three units such as VDD. At this time, the first pass voltage, the second pass voltage and the third pass voltage may also be equal. A fourth bias voltage such as 0V is applied to word lines of all memory cells in the memory string to turn off respective channels and no electron is left in the channel.

In some implementations, the operation method may further include: In the

programming stage of the program operation on the memory cell, applying a fourth pass voltage to the word line coupled to unselected memory cells in the memory string and the first dummy word line and applying the program voltage to the word line coupled to the memory cell.

It is to be noted that the above-described operations are in the programming stage after the pre-charge stage. In this stage, a fourth pass voltage is applied to the word line coupled to unselected memory cells in the memory string and the first dummy word line and a program voltage is applied to the word line coupled to the memory cell, wherein the fourth pass voltage may be greater than the afore-mentioned first pass voltage, the second pass voltage and the third pass voltage.

To understand the operation method provided in implementations of the present

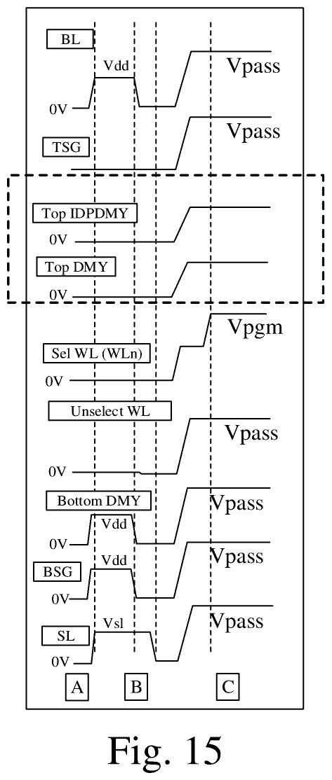

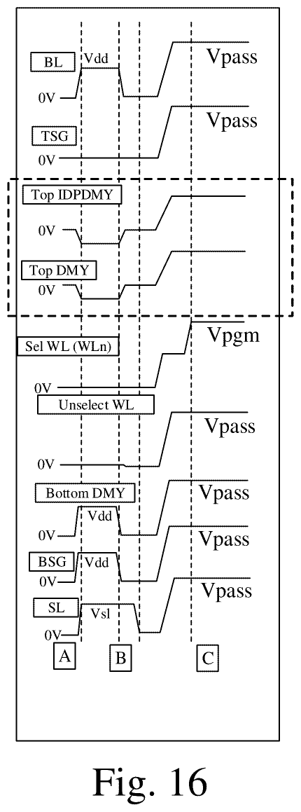

disclosure, as shown in FIG. 15, which illustrates the timing diagram of applying voltages while performing program operation on memory cells nearby a certain plug in a memory. As shown in FIG. 16, which illustrates the timing diagram of applying voltages while performing program operation on memory cells nearby a certain plug in a memory string as provided in an implementation of the present disclosure. It is to be noted that each memory string in the memory shown in FIGS. 15 and 16 includes a first sub-string and a second sub-string connected by a plug, wherein the first sub-string includes a top select gate, the second sub-string includes a first dummy memory cell, a second dummy memory cell, a plurality of memory cells, a third dummy memory cell and a bottom select gate. In FIGS. 15 and 16, BL is the bit line, TSG is the top select gate; Top IDPDMY is the first dummy memory cell; Top DMY is the second dummy memory cell; Sel WL (WLn) is the word line corresponding to the selected memory cell; Unselect WL is the word line corresponding to the unselected memory cell; Bottom DMY is the third dummy memory cell. The bottom select gate (BSG) is not shown in FIGS. 15 and 16. Generally, the bottom select gate (BSG) in the selected memory string is turned on. This will not be described any more herein since it's not the emphasis of the technical solution.

With the memory having the above-described structure, in the pre-charge stage of the program operation, the second bias voltage (such as 0V) is applied via the first dummy word line coupled to the Top IDPDMY and the second dummy word line coupled to the Top DMY. Due to the special structure of the plug, while programming memory cells close to the plug, large number of electrons would accumulate at the plug, thereby interfering with the programming. In the pre-charge stage, the remaining voltages are as follows. Voltages applied on TSG, Sel WL and Unselect WL are all 0V. Voltages applied on BL, Bottom DMY and bottom select gate (BSG) are all Vdd. The voltage applied on SL is Vs1. In the programming stage, the Sel WL is applied with the program voltage Vpgm; and others are applied with pass voltage Vpass.

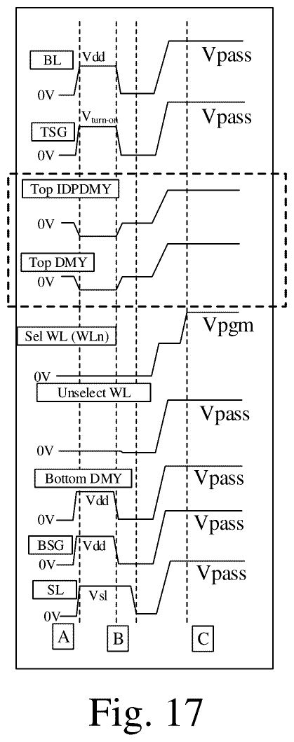

According to the solution provided in implementations of the present disclosure, as shown in FIG. 16, a negative bias voltage is applied to the first dummy word line coupled to the Top IDPDMY and the second dummy word line coupled to the Top DMY to couple a negative potential into the channel corresponding to the first dummy cell and the channel corresponding to the second dummy memory cell, thereby preventing electrons at the plug from moving towards the word line of the memory cells. The specific effect is shown in FIG. 17. The remaining voltages are as follows. Voltages applied on TSG, Sel WL and Unselect WL are all 0V. Voltages applied on BL, Bottom DMY and bottom select gate (BSG) are all Vdd. The voltage applied on SL is Vs1. In the programming stage, the Sel WL is applied with the program voltage Vpgm; and others are applied with pass voltage Vpass. It is to be noted that FIG. 17 only illustrates preventing electrons at the plug from moving towards the word line of memory cells. In fact, if now the threshold voltage of the first dummy memory cell Top IDPDMY is increased, it is also possible to have the control gate of the Top IDPDMY to enhance gate control at the plug, thereby reducing electron residue at the plug.

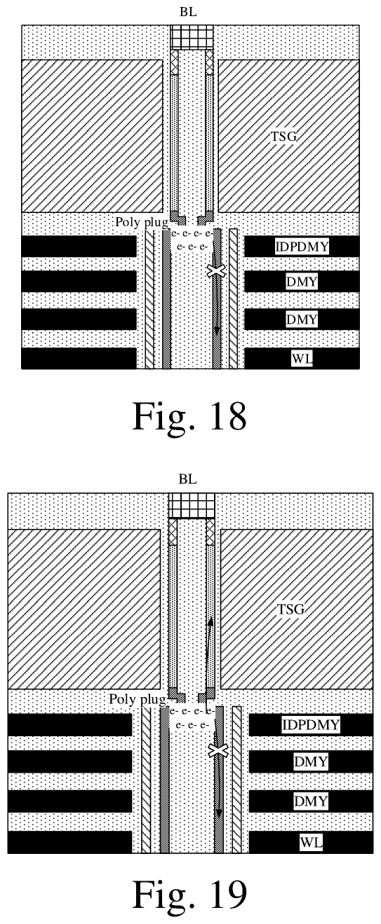

As shown in FIG. 18, on the basis of the technical solution illustrated in FIG. 16, an implementation of the present disclosure further provides an operation method in which in the pre-charge stage, a first pass voltage Vtum-on is applied to the top select line coupled to the top select gate such that the top select gate is turned on, which in turn enables electrons at the plug to move towards the bit line under the action of the bit line positive biasing voltage, thereby drawing electrons out of the channel via the bit line and improving the programming interference. The specific effect is shown in FIG. 19.

It is to be noted that in FIGS. 15, 16 and 18, there are three stages labeled as A, B and C. In fact, the part before applying the program voltage to the Sel WL may be considered as the pre-charge stage and the part after applying the program voltage Vpgm to the Sel WL may be considered as the programming stage.

With the operation method provided in implementations of the present disclosure, in order to improve the programming interference caused by electron accumulated at the plug, the present disclosure can apply a negative bias voltage to the Top IDPDMY and the Top DMY in the pre-charge stage to couple a negative potential into the channel, thereby preventing electrons at the poly plug from moving towards WL; and/or adjust the threshold voltage of the Top IDPDMY to increase it such that the Top IDPDMY is in a high threshold voltage stage, which can reduce electrons accumulated at the poly plug. And based on the above-described three schemes, in the pre-charge stage, it is also possible to make the TSG conduct voltages so as to draw electrons at the plug out of the channel via the bit line, thereby reducing electrons at the plug.

An implementation of the present disclosure further provides a memory device including: a memory stack structure; a select stack structure; a plurality of memory strings, wherein the select stack structure is over the memory stack structure; each memory string includes a first sub-string and a second sub-string connected by a plug; the first sub-string penetrates through the select stack structure; the second sub-string penetrates through the memory stack structure; and the second sub-string includes a first dummy memory cell adjacent to the plug and a plurality of memory cells; a peripheral circuit connected with the plurality of memory strings and configured to program the first dummy memory cell; and/or apply a first bias voltage to a first dummy word line coupled to the first dummy memory cell in the pre-charge stage of the program operation of the memory cell close to the plug in a memory string, the first bias voltage being a negative voltage.

In some implementations, the peripheral circuit is further configured to: if only the first dummy memory cell is to be programmed, apply a second bias voltage to the first dummy word line in the pre-charge stage, the second bias voltage being greater than the first bias voltage.

In some implementations, the first sub-string includes a top select gate, the peripheral circuit is further configured to: in the pre-charge stage, apply a first pass voltage to the top select line coupled to the top select gate.

In some implementations, the first sub-string includes a top select gate; the second sub-string further includes at least one second dummy memory cell and a second dummy word line coupled to the at least one second dummy memory cell respectively; the peripheral circuit is further configured to: apply a third bias voltage to the second dummy word line in the pre-charge stage, the third bias voltage being a negative voltage.

In some implementations, the peripheral circuit is further configured to: in the pre-charge stage, apply a first pass voltage to the top select line coupled to the top select gate.

In some implementations, the memory string is coupled to the bit lines via the top select gate, the peripheral circuit is further configured to: apply a first pre-charge voltage to the bit line in the pre-charge stage, the first pre-charge voltage being greater than 0.

In some implementations, the second sub-string further includes a bottom select gate, the memory string is connected with the source line via the bottom select gate, and the peripheral circuit is further configured to: in the pre-charge stage, apply a second pass voltage to the bottom select line coupled to the bottom select gate; and applying a second pre-charge voltage to the source line; wherein the second pre-charge voltage is greater than 0.

In some implementations, the second sub-string further includes at least one third

dummy memory cell between the plurality of memory cells and the bottom select gate, and the peripheral circuit is further configured to: apply a third pass voltage to the at least one third dummy memory cell in the pre-charge stage.

In some implementations, the peripheral circuit is further configured to: in the pre-charge stage, applying a fourth bias voltage to the word line coupled to the plurality of memory cells.

In the programming stage of the program operation on the memory cell, applying a fourth pass voltage to the word line coupled to unselected memory cells in the memory string and the first dummy word line and applying the program voltage to the word line coupled to the memory cell.

It is to be noted that the above-described memory is configured to carry out the above-described operation method. Herein, the explanation of steps in the operations has been set forth in detail and will not be repeated here.

In some implementations, the memory device further includes: a plurality of memory channel structure penetrating through the memory stack structure each corresponding to one second sub-string; top select gate cut structures and a plurality of select channel structures penetrating through the select stack structure, each select channel structure corresponding to one first sub-string; wherein the plurality of select channel structures and the plurality of memory channel structures are connected respectively; the plurality of select channel structures are arranged in rows along the extending direction of the top select gate cut structure; and the top select gate cut structures extend between adjacent rows of the select channel structures.

In some implementations, there are multiple rows of select channel structures between adjacent top select gate cut structures.

In some implementations, the select channel structure includes a dielectric core and a conductive layer and an insulating layer surrounding the dielectric core successively, wherein the conductive layer contacts the memory channel structure.

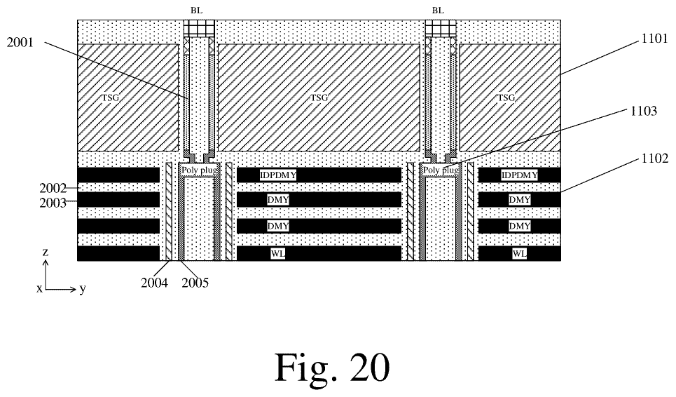

It is to be noted that the practical physical structure is shown in FIG. 20 which illustrates a physical structure diagram of a memory provided in an implementation of the present disclosure. In FIG. 20, only two memory strings are illustrated. In practical application process, the number of memory strings may be hundreds, thousands, tens of thousands etc. The number of memory strings contained in the memory is not limited herein, which may be selected depending upon practical conditions. For the memory shown in FIG. 20, its structure may include a memory stack structure, a plurality of memory channel structures penetrating through the memory stack structure, a select stack structure, a plurality of select channel structures and top select gate cut structures penetrating through the select stack structure (not shown in Figs, visible in X-Y direction, referring to FIGS. 6-8), wherein each memory channel structure penetrating through the memory stack structure corresponds to one second sub-string (1102 in the figure); each select gate structure penetrating through the select stack structure corresponds to one first sub-string (1101 in the figure); and the first sub-string and the second sub-string connected from top to bottom by the plug (1103 in the figure) form a memory string. In practice, the plurality of select channel structures and the plurality of memory channel structures are connected respectively; the plurality of select channel structures are arranged in rows along the extending direction of the top select gate cut structure; and the top select gate cut structures extend between adjacent rows of the select channel structures. There are multiple rows of select channel structures between adjacent top select gate cut structures, wherein as shown in FIG. 20, the memory channel structure corresponding to the second sub-string 1102 mainly includes for example the memory layer 2004 and the memory channel layer 2005. It should be known that the memory channel structure further includes other necessary structures that will not be described in detail here.

As shown in FIG. 20, the select channel structure corresponding to the first sub-string 1101 mainly includes a select channel layer 2001, and may further include: a dielectric core and a conductive layer and an insulating layer surrounding the dielectric core successively, wherein the conductive layer contacts the memory channel structure. Furthermore, the second sub-string 1102 further includes alternatively stacked conductive medium 2003 and insulating medium 2002.

An implementation of the present disclosure further provides a memory system including: a memory as described in any of the above aspects; and a memory controller coupled to the memory and configured to control the memory device.

In some implementations, the memory system is included in a solid-state disk SSD or a memory card.

It is to be noted that the memory system contains the afore-mentioned memory device. Accordingly, terminologies used herein have been explained in detail in the afore-mentioned memory and are equally applicable and will not be repeated. It should be understood that, what has been described herein are only structures of the memory system closely relevant to the technical solution of the present disclosure. For the structure and description of the memory system shown in FIGS. 1 to 5, the memory system provided in the present disclosure is also contained and applicable. The memory system further includes structures that are not shown but are necessary for normal operation of the memory system. These structures will not be described in detail in the present disclosure for the purpose of brevity.

It should be understood that in the several implementations provided in the present disclosure, the disclosed apparatuses and methods may be implemented in other ways. The above-described apparatus implementations are only schematic. For example, the division of units is only a logical function division and there may be other division manners upon practical implementation. For example, a plurality of units or parts may be combined or integrated into another system, or some features may be omitted or not executed. In addition, the coupling, or direct coupling or communication connection among the illustrated or discussed constituent parts may be indirect coupling or communication connection through some interfaces, apparatuses or units, and may be electrical, mechanical or other forms.

The units described as separate components above may be or may not be physically separate. Components illustrated as units may be or may not be physical units, that is, they may be located at one place or distributed among a plurality of network units. Some or all units may be selected according to practical demands to achieve the object of the solution of the implementations.

Additionally, functional units in implementations of the present disclosure may all be integrated in one processing unit. It is also possible that the units are separate units respectively. Two or more units may be integrated in one unit. The above-described integrated units may be implemented in the form of hardware, or in form of hardware plus software functional units.

Those of ordinary skill in the art would understand that all or partial steps for implementing the above-described method implementations may be accomplished by hardware related to program instructions, the above-described programs may be stored in a computer readable storage medium which, upon execution, carries out steps containing the above-described method implementations, while the afore-mentioned storage medium includes various media that may store program codes such as a mobile storage apparatus, a read-only memory (ROM), a random access memory (RAM), a magnetic disk or an optical disk.

Alternatively, the above-described integrated units of the present disclosure may also be stored in a computer readable storage medium if they are implemented in the form of software functional modules and sold or used as stand-alone products. Based on this understanding, the technical solution of the implementations of the present disclosure may be essentially, or parts thereof embodied in form of software products that are stored in a storage medium and contain instructions to cause a computing apparatus such as a personal computer, a server or a network device to carry out all or part of the method described in implementations of the present disclosure. The afore-mentioned storage medium includes various media that can store program codes such as a mobile storage apparatus, a ROM, a RAM, a magnetic disk or an optical disk.

An implementation of the present disclosure further provides an electronic apparatus including: the memory system as described in any of the above aspects; and a host coupled to the memory system and configured to control the memory system.

It is to be noted that the powering circuits and powering method for the electronic apparatus and the afore-described memory belong to the same inventive concept. The electronic apparatus includes the afore-mentioned memory system. Accordingly, the terminologies used herein have been explained in detail in the above description and are equally applicable and will not be repeated. It should be understood that, what has been described herein are only structures closely relevant to the technical solution of the present disclosure. For the structure and description of the electronic apparatus shown in FIG. 1, the electronic apparatus provided in the present disclosure is also contained and applicable. The electronic apparatus further includes structures that are not shown but are necessary for normal operation of the electronic apparatus. These structures will not be described in detail in the present disclosure for the purpose of brevity.

The above description is intended to be illustrative rather than limiting. For example, the above-described examples (or one or more aspects thereof) may be used in combination with each other. Other implementations may be used, such as those available for one of ordinary skill in the art upon reading the above description. It should be understood that, it will not be used to interpret or limit the scope or meaning of the claims. Furthermore, in the above detailed description, various features may be combined to simplify the present disclosure. It should not be understood as meaning the disclosed features that have not been claimed are essential for any claims. To the contrary, the disclosed subject may lie in less than all features of specific disclosed implementations. Accordingly, the appended claims are hereby incorporated in the detailed description, wherein each claim serves as a separate implementation independently and it is contemplated these implementations may be combined with each other in various combinations or permutations. The scope of the present disclosure should be determined by the full scope of the appended claims and equivalents accorded by these claims.

What is claimed is:

1. A method of operating a memory device, comprising:
programming a first dummy memory cell in a memory string of the memory device, wherein the first dummy memory cell is located adjacent to a plug between a first sub-string of the memory string penetrating through a select stack structure and a second sub-string of the memory string penetrating through the memory stack structure; and
applying a first bias voltage to a first dummy word line coupled to the first dummy memory cell in a pre-charge stage of a program operation of a memory cell close to the plug in the memory string, the first bias voltage being a negative voltage.

2. The method of claim 1, further comprising:
if only the first dummy memory cell is programmed, applying a second bias voltage to the first dummy word line in the pre-charge stage;
wherein the first bias voltage is negative, and the second bias voltage is higher than the first bias voltage.

3. The method of claim 1, further comprising:
in the pre-charge stage, applying a first pass voltage to a top select line coupled to a top select gate in the first sub-string.

4. The method of claim 1, further comprising:
in the pre-charge stage, applying a third bias voltage to a second dummy word line coupled to a second dummy memory cell in the second sub-string,
wherein the third bias voltage is negative.

5. The method of claim 3, further comprising:
in the pre-charge stage, applying a first pre-charge voltage to a bit line coupled to the memory string via the top select gate, wherein the first pre-charge voltage is positive.

6. The method of claim 1, further comprising:
in the pre-charge stage, applying a second pass voltage to a bottom select line coupled to a bottom select gate in the second sub-string; and
applying a second pre-charge voltage to a source line coupled to the memory string via the bottom select gate, wherein the second pre-charge voltage is positive.

7. The method of claim 6, further comprising:
in the pre-charge stage, applying a third pass voltage to a third dummy memory cell between the plurality of memory cells and the bottom select gate.

8. The method of claim 1, further comprising:
in the pre-charge stage, applying a fourth bias voltage to a word line coupled to one of the plurality of memory cells.

9. The method of claim 1, further comprising:
in a programming stage of the program operation, applying a fourth pass voltage to a unselected word line coupled to a unselected memory cell in the memory string and to the first dummy word line; and
applying a program voltage to a word line coupled to the memory cell.

10. A memory device, comprising:
a memory stack structure;
a select stack structure on the memory stack structure;
a memory string comprising:
a first sub-string penetrating through the select stack structure, and a second sub-string penetrating through the memory stack structure, and comprising:
a first dummy memory cell adjacent to a plug, and a plurality of memory cells;
a peripheral circuit connected with the memory string and configured to:
program the first dummy memory cell, and apply a first bias voltage to a first dummy word line coupled to the first dummy memory cell in a pre-charge stage of a program operation of one of the plurality of memory cells close to the plug, wherein the first bias voltage is negative.

11. The memory device of claim 10, wherein the peripheral circuit is further configured to:
if only the first dummy memory cell is programmed, apply a second bias voltage to the first dummy word line in the pre-charge stage,
wherein the second bias voltage is higher than the first bias voltage.

12. The memory device of claim 10, wherein:
the first sub-string comprises a top select gate; and
the peripheral circuit is further configured to apply a first pass voltage to a top select line coupled to the top select gate in the pre-charge stage.

13. The memory device of claim 10, wherein:
the second sub-string further comprises a second dummy memory cell; and
the peripheral circuit is further configured to apply a third bias voltage to a second dummy word line coupled to the second dummy memory cell in the pre-charge stage, the third bias voltage being negative.

14. The memory device of claim 12, wherein:
the memory string is coupled to a bit line via the top select gate; and
the peripheral circuit is further configured to apply a first pre-charge voltage to the bit line in the pre-charge stage, the first pre-charge voltage being positive.

15. The memory device of claim 12, wherein:
the second sub-string further comprises a bottom select gate;
the memory string is coupled to a source line via the bottom select gate; and
the peripheral circuit is further configured to:
apply a second pass voltage to a bottom select line coupled to the bottom select gate in the pre-charge stage; and
apply a second pre-charge voltage to the source line, the second pre-charge voltage being positive.

16. The memory device of claim 15, wherein:
the second sub-string further comprises a third dummy memory cell between the plurality of memory cells and the bottom select gate; and
the peripheral circuit is further configured to apply a third pass voltage to the third dummy memory cell in the pre-charge stage.

17. The memory device of claim 10, wherein the peripheral circuit is further configured to:
in the pre-charge stage, apply a fourth bias voltage to a word line coupled to one of the plurality of memory cells in the pre-charge stage.

18. The memory device of claim 10, wherein the peripheral circuit is further configured to:
in a programming stage of the program operation on the memory cell, apply a fourth pass voltage to an unselected word line coupled to a unselected memory cell in the memory string and to the first dummy word line, and apply a program voltage to a word line coupled to the memory cell.

19. The memory device of claim 10, wherein the memory string is a NAND memory string.

20. A memory system, comprising:
a memory device comprising:
a memory stack structure;
a select stack structure on the memory stack structure;
a memory string comprising:
a first sub-string penetrating through the select stack structure, and a second sub-string penetrating through the memory stack structure, and comprising:
a first dummy memory cell adjacent to a plug, and a plurality of memory cells;
a peripheral circuit connected with the memory string and configured to:
program the first dummy memory cell, and apply a first bias voltage to a first dummy word line coupled to the first dummy memory cell in a pre-charge stage of a program operation of one memory cell close to the plug; and
a memory controller coupled to the memory device and configured to control the memory device through the peripheral circuit.
